(19) United States
(12) Patent Application Publication
(10) Pub. No.: US 2026/0173825 A1
(43) Pub. Date: Jun. 18, 2026

(54) SEMICONDUCTOR STRUCTURE

(71) Applicant: United Semiconductor (Xiamen) Co., Ltd., Xiamen (CN)

(72) Inventors: Feng Xie, Shamen City (CN); Hong Fu Xu, Shamen City (CN); Bing Du, Xiamen (CN); Hailong Gu, Singapore (SG); Wen Yi Tan, Xiamen (CN)

(73) Assignee: United Semiconductor (Xiamen) Co., Ltd., Xiamen (CN)

(21) Appl. No.: 19/019,481

(22) Filed: Jan. 14, 2025

(30) Foreign Application Priority Data
Dec. 17, 2024 (CN) 202411864000.6

(51) Int. Cl. H01L 21/66; H10D 1/68

(52) U.S. Cl. CPC H10P 74/277; H10D 1/714; H10D 1/716

(57) ABSTRACT

A semiconductor structure includes a semiconductor wafer having integrated circuit die regions and a scribe lane between the integrated circuit die regions. A first monitor structure is disposed in the scribe lane. The first monitor structure is composed of consecutive n layers of MOM capacitors disposed in multiple metal layers.

### BACKGROUND OF THE INVENTION

### 1. Field of the Invention

This invention generally relates to a semiconductor structure, and more specifically, to a metal-oxide-metal (MOM) capacitor monitoring structure.

### 2. Description of the Prior Art

The miniaturization of IC devices has led to an increased number of interconnect metal layers. This trend poses significant challenges to the quality and reliability of the interconnect fabrication process. Existing monitoring systems and techniques are inadequate to ensure the desired level of quality and yield.

Chemical Mechanical Polishing (CMP) is a critical step in semiconductor manufacturing used to planarize surfaces between metal deposition layers. However, CMP can sometimes lead to dishing, a phenomenon where the center of a pre-layer such as an inter-metal dielectric (IMD) layer between two adjacent metal lines is polished away more than the edges, resulting in a concave surface profile. This can negatively impact the performance and reliability of the interconnect.

### SUMMARY OF THE INVENTION

It is one objective of the present invention to provide an improved semiconductor monitoring structure in order to address the shortcomings and deficiencies of the prior art.

Another objective of the present invention is to monitor the difference in CMP dishing caused by the loading effect between dense and isolated patterns of metal lines.

One aspect of the invention provides a semiconductor structure including a semiconductor wafer comprising a plurality of integrated circuit die regions and at least one scribe lane between the plurality of integrated circuit die regions; and a first monitor structure disposed in the scribe lane, wherein the first monitor structure is composed of consecutive n layers of metal-oxide-metal (MOM) capacitors disposed in a plurality of metal layers.

According to some embodiments, the semiconductor structure further includes a second monitor structure disposed in the scribe lane and spaced apart from the first monitor structure, wherein the second monitor structure is composed of consecutive m layers of MOM capacitors disposed in the plurality of metal layers, wherein m is smaller than n.

According to some embodiments, n and m are integrals ranging between 3 and 12.

According to some embodiments, n=6, and m is between 2-5.

According to some embodiments, one of the consecutive m layers of MOM capacitors of the second monitor structure is disposed in a topmost metal layer of the plurality of metal layers.

According to some embodiments, each of the n layers of MOM capacitors and the m layers of MOM capacitors comprises a pair of comb-like components, each having a plurality of elongated fingers, respectively, arranged in parallel in an interdigitated manner and spaced apart from each other by a dielectric layer.

According to some embodiments, each of the plurality of elongated fingers has a length of 18 micrometers and a width of 0.0405 micrometers, and wherein a spacing between adjacent two of the plurality of elongated fingers is 0.0405 micrometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a plan view illustrating a wafer.

FIG. 2 is a plan view of the monitoring structure in FIG. 1.

FIG. 3 and FIG. 4 respectively illustrate three-dimensional cross-sectional schematic diagrams of selected portions of the MOM capacitor monitoring structure indicated by the dashed rectangular area marked “C” in FIG. 2.

FIG. 5 is a three-dimensional cross-sectional schematic diagram of a semiconductor monitoring structure according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

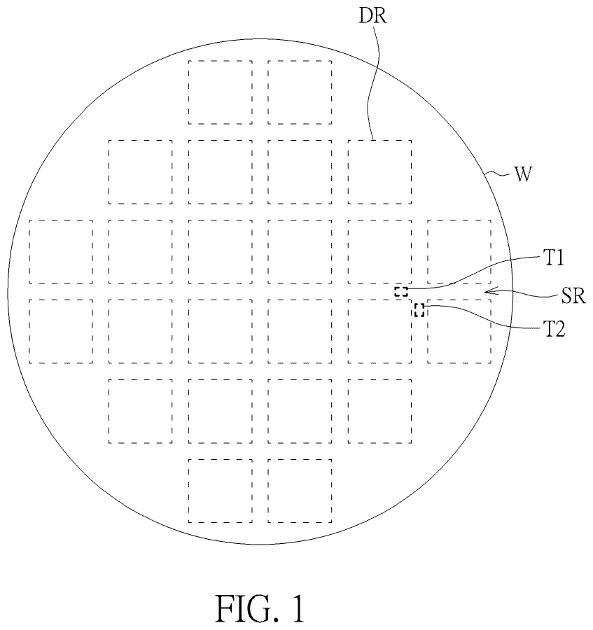

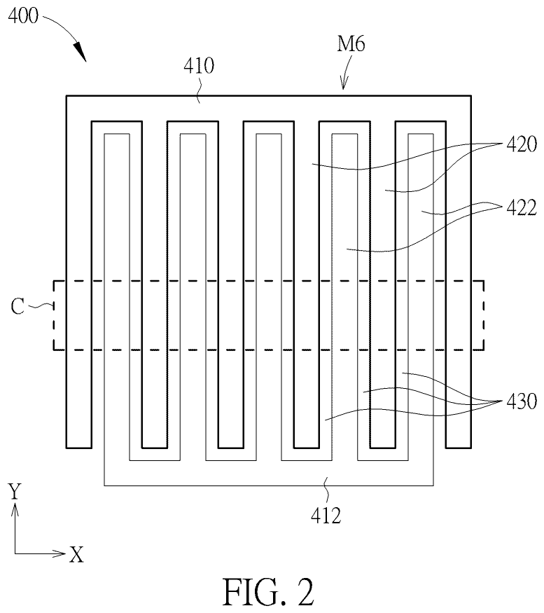

Please refer to FIG. 1 and FIG. 2. FIG. 1 is a plan view illustrating a wafer, and FIG. 2 is a plan view of the monitoring structure in FIG. 1. As shown in FIG. 1, multiple integrated circuit die regions DR (indicated by dashed lines) can be disposed on the silicon wafer W, and scribe lanes SR can be provided between the integrated circuit die regions DR. According to an embodiment of the present invention, multiple monitoring structures (also known as test keys) can be disposed on the scribe lanes SR. For the sake of simplicity, only monitoring structures T1 and T2 are illustrated in the figures. According to an embodiment of the present invention, for example, the monitoring structures T1 and T2 are metal-oxide-metal (MOM) capacitor monitoring structures.

As shown in FIG. 2, monitoring structures T1 and T2 may be, for example, the MOM capacitor monitoring structure 400, including capacitor elements formed in continuous n metal layers, such as six metal layers, which may be referred to as “Metal-1 (or M1)” to “Metal-6 (or M6),” while only the top metal layer M6 is shown in FIG. 2. Each metal layer M1-M6 may have a similar configuration, such that each metal layer M1-M6 may have a structure similar to the top metal layer M6 shown in FIG. 2. The metal layer M6 includes a pair of metal comb-shaped elements 410 and 412, each metal comb-shaped element 410 and 412 respectively having a plurality of fingers 420 and 422. These fingers 420 and 422 are arranged in parallel in an interdigitated (interleaved) manner and are spaced apart from each other by a dielectric material 430. According to an embodiment of the present invention, the fingers 420 and 422 may be copper metal fingers, electrically connected to positive and negative electrodes, respectively.

According to an embodiment of the present invention, for example, each finger 420 and 422 has a length of 18 micrometers and a width of 0.0405 micrometers, and the spacing between two adjacent fingers 420 and 422 is, for example, 0.0405 micrometers.

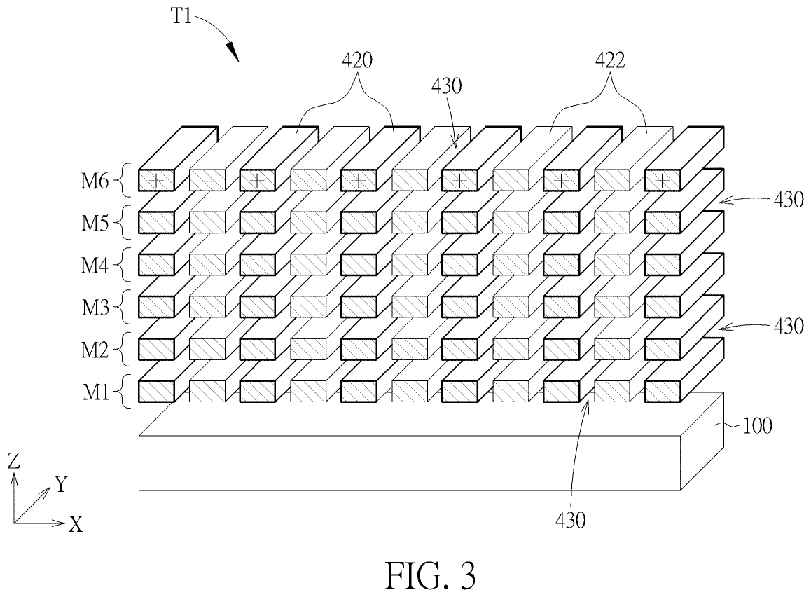

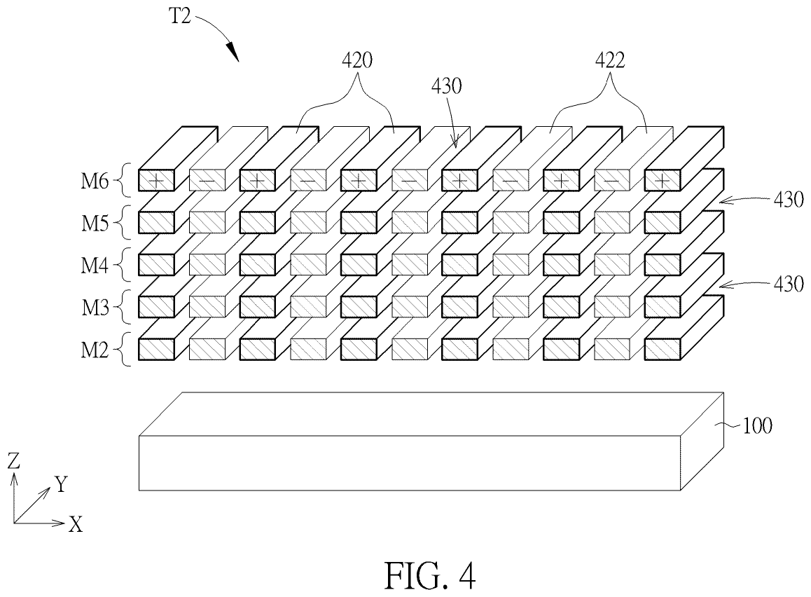

Please refer to FIG. 3 and FIG. 4, which respectively illustrate three-dimensional cross-sectional schematic diagrams of selected portions of the MOM capacitor monitoring structure 400 indicated by the dashed rectangular area marked “C” in FIG. 2 for monitoring structures T1 and T2. As shown in FIG. 3, the monitoring structure T1 includes consecutive n layers of the multiple metal layers on the substrate 100, such as the fingers 420 and 422 in metal layers M1-M6, arranged in parallel in an interdigitated manner and separated from each other by a dielectric material 430. According to an embodiment of the present invention, the substrate 100 is, for example, a silicon substrate, but is not limited thereto. As shown in FIG. 4, the monitoring structure T2 includes consecutive m layers (where m is less than n) of the multiple metal layers on the substrate 100, such as the fingers 420 and 422 in metal layers M2-M6, which are also arranged in parallel in an interdigitated manner and separated from each other by the dielectric material 430.

It should be understood that the six metal layers M1-M6 in the figures are for illustrative purposes only. In some embodiments, both n and m can be integers between 3 and 12. According to some embodiments of the present invention, for example, n=6 and m is between 2 and 5. According to some embodiments of the present invention, one of the consecutive m layers of metal-oxide-metal capacitors of the monitoring structure T2 must be disposed in the uppermost metal layer of the plurality of metal layers.

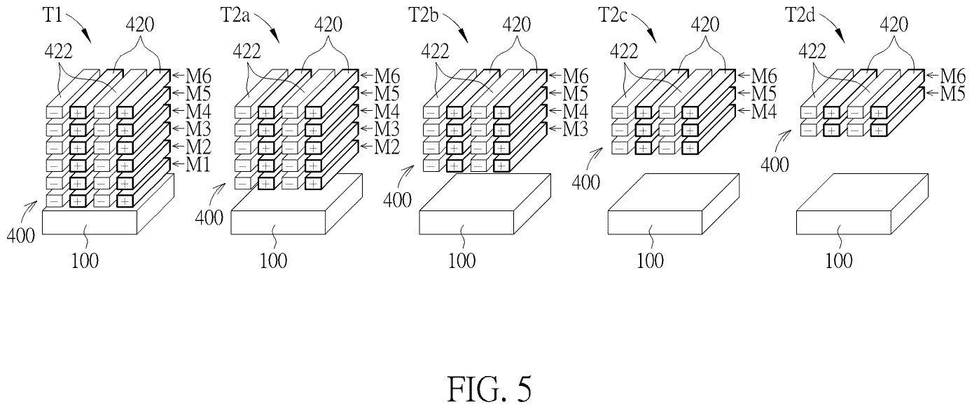

Please refer to FIG. 5, which is a three-dimensional cross-sectional schematic diagram of a semiconductor monitoring structure according to another embodiment of the present invention. As shown in FIG. 5, according to an embodiment of the present invention, in addition to the monitoring structure T1, a plurality of monitoring structures T2a-T2d can also be arranged on the scribe lane SR, including interdigitated fingers 420 and 422 in consecutive m layers (m is less than n) of the plurality of metal layers distributed on the substrate 100, which are arranged in parallel in an interdigitated manner and separated from each other by the dielectric material 430. According to an embodiment of the present invention, for example, the capacitance structure 400 of the monitoring structure T1 is distributed in consecutive n layers of the plurality of metal layers on the substrate 100, for example, n=6, and the capacitance structure 400 of the monitoring structures T2a-T2d is distributed in consecutive m layers (m is less than n) of the plurality of metal layers on the substrate 100, for example, for the monitoring structure T2a, m=5, for the monitoring structure T2b, m=4, for the monitoring structure T2c, m=3, and for the monitoring structure T2d, m=2.

In some embodiments, any two or three combinations of monitoring structures T2a-T2d can be selected. The sensitivity of monitoring structures T2a-T2d is highest for monitoring structure T2d, followed by T2c, then T2b, and finally T2a. If there is insufficient space on the scribe lane SR, only the most sensitive monitoring structure, T2d, can be set up.

By placing a MOM capacitor monitoring structure with capacitor structures 400 of varying layers on the scribe line, one can effectively monitor, in real-time during Final Wafer Acceptance Test (FWAT), metal broken or metal bridge issues caused by pre-layer dishing due to Chemical Mechanical Polishing (CMP) processes. It also achieves the objective of monitoring the CMP dishing differences caused by loading effects between dense and isolated patterns of metal lines.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a semiconductor wafer comprising a plurality of integrated circuit die regions and at least one scribe lane between the plurality of integrated circuit die regions; and
a first monitor structure disposed in the scribe lane, wherein the first monitor structure is composed of consecutive n layers of metal-oxide-metal (MOM) capacitors disposed in a plurality of metal layers.

2. The semiconductor structure according to claim 1 further comprising: a second monitor structure disposed in the scribe lane and spaced apart from the first monitor structure, wherein the second monitor structure is composed of consecutive m layers of MOM capacitors disposed in the plurality of metal layers, wherein m is smaller than n.

3. The semiconductor structure according to claim 2, wherein n and m are integrals ranging between 3 and 12.

4. The semiconductor structure according to claim 2, wherein n=6, and m is between 2-5.

5. The semiconductor structure according to claim 2, wherein one of the consecutive m layers of MOM capacitors of the second monitor structure is disposed in a topmost metal layer of the plurality of metal layers.

6. The semiconductor structure according to claim 2, wherein each of the n layers of MOM capacitors and the m layers of MOM capacitors comprises a pair of comb-like components, each having a plurality of elongated fingers, respectively, arranged in parallel in an interdigitated manner and spaced apart from each other by a dielectric layer.

7. The semiconductor structure according to claim 6, wherein each of the plurality of elongated fingers has a length of 18 micrometers and a width of 0.0405 micrometers, and wherein a spacing between adjacent two of the plurality of elongated fingers is 0.0405 micrometers.
